(19) United States
(12) Patent Application Publication
(10) Pub. No.: US 2013/0224930 A1
(43) Pub. Date: Aug. 29, 2013

(54) METHOD FOR MANUFACTURING VARIABLE RESISTANCE ELEMENT

(71) Applicants: Koji Arita, Toyama (JP); Takumi Mikawa, Shiga (JP)

(72) Inventors: Koji Arita, Toyama (JP); Takumi Mikawa, Shiga (JP)

(21) Appl. No.: 13/805,198

(22) PCT Filed: Jun. 21, 2011
(86) PCT No.: PCT/JP11/03512

§ 371 Date: Dec. 18, 2012

(30) Foreign Application Priority Data
Jun. 21, 2010 (JP) 2010-140081

(51) Int. Cl. H01L 45/00

(52) U.S. Cl. CPC H01L 45/16
USPC 438/382

(57) ABSTRACT

A variable resistance element manufacturing method includes: forming a conductive plug in an interlayer insulating film on a substrate; planarizing an upper surface of the insulating film such that an upper part of the conductive plug protrudes from an upper surface of the insulating film by removing (i) a depression in the insulating film formed around the conductive plug and (ii) a depression in the insulating film formed across a plurality of conductive plugs; forming, on the insulating film and the plug, a lower electrode layer electrically connected to the plug; planarizing an upper surface of the lower electrode layer to remove a protruding part on the upper surface of the lower electrode layer; forming, on the lower electrode layer, a variable resistance layer; forming an upper electrode layer on the variable resistance layer; and forming a lower electrode, the variable resistance layer, and an upper electrode layer.

### TECHNICAL FIELD

The present invention relates to a method for manufacturing a variable resistance element in which a resistance value reversibly changes based on an electrical signal, and the variable resistance element manufactured by the manufacturing method.

### BACKGROUND ART

In recent years, research and development have been done on a non-volatile memory device using an element known as a variable resistance element as a memory element in a memory cell. The variable resistance element is an element in which a resistance value reversibly changes according to an electrical signal, and information corresponding to a resistance value is stored in a non-volatile manner.

FIG. 14 is a cross-sectional view schematically illustrating a configuration of a conventional memory cell including a variable resistance element illustrated in the patent literature 1. A memory cell 900 is a 1T1R (one transistor and one resistor) memory cell in which a selection transistor 906 and a variable resistance element 910 are connected in series. The selection transistor 906 includes a source region 902 and a drain region 903 that are formed on the substrate 901, and a gate electrode 905 formed on a gate oxide film 904. The variable resistance element 910 includes a variable resistance layer 908, a lower electrode 907 and an upper electrode 909 interposing the variable resistance layer 908.

A conductive plug 916 is formed in an interlayer insulating film 914, and electrically connects the drain region 903 in the selection transistor 906 and the lower electrode 907 of the variable resistance element 910. A conductive plug 917 electrically connects a metal line 912 which serves as a bit line and the upper electrode 909. A conductive plug 918 electrically connects a metal line 913 which serves as a source line and the source region 902. The gate electrode 905 is electrically connected to a word line (not illustrated). In the memory cell 900, the state of the variable resistance layer 908 can be changed from a low resistance state to a high resistance state, or from the high resistance state to the low resistance state, by applying predetermined electrical pulses between the metal line (bit line) 912 and the metal line (source line) 913, and on the word line.

The patent literature 1 discloses a 1T1R memory device in which an oxide having perovskite crystal structure such as Pr₁₋ₓCaₓMnO₃ (PCMO), La₁₋ₓSrₓMnO₃ (LSMO) is used for the variable resistance element. The patent literatures 2 and 3 disclose a 1T1R memory device in which tantalum oxide which is an oxide of a transition metal is used for the variable resistance element.

In addition, a memory device in which 1D1R (one diode and one resistor) memory cells each including a diode and a variable resistance element connected in series are arranged. In the 1D1R memory device, the diode prevents a bypass current to a non-selected memory cell from flowing.

The patent literatures 4 and 5 disclose 1D1R memory devices. The patent literature 4 discloses a 1D1R memory device which includes a Schottky diode and a unipolar variable resistance element. The patent literature 5 discloses a 1D1R memory device which includes a bipolar current steering element and a bipolar variable resistance element. As a bipolar current steering element, two-terminal devices such as a metal-insulator-metal (MIM) diode, a metal-semiconductor-metal (MSM) diode, a varistor are known, for example.

### CITATION LIST

### Patent Literature

[Patent Literature 1] Japanese Unexamined Patent Application Publication No. 2005-25914
[Patent Literature 2] W02008/59701
[Patent Literature 3] W02009/50833
[Patent Literature 4] Japanese Unexamined Patent Application Publication No. 2004-319587
[Patent Literature 5] Japanese Unexamined Patent Application Publication No. 2006-203098
[Patent Literature 6] Japanese Unexamined Patent Application Publication No. 2004-241508

### SUMMARY OF INVENTION

### Technical Problem

A method for manufacturing a variable resistance element 910 (FIG. 14) illustrated as a conventional example shall be described as follows with reference to FIG. 15.

(a) to (e) in FIG. 15 are process diagrams schematically illustrating an example of a method for manufacturing a conventional 1T1R memory cell. (a) in FIG. 15 is a cross-sectional view after a contact hole is formed. (b) in FIG. 15 is a cross-sectional view after a conductive material is filled in the contact hole. (c) in FIG. 15 is a cross-sectional view after a conductive plug is formed. (d) in FIG. 15 is a cross-sectional view after a material for the upper electrode in the variable resistance element is formed. (e) in FIG. 15 is a cross-sectional view after the variable resistance element is formed.

First, the interlayer insulating film 914 comprises an insulator such as silicon dioxide (SiO₂) is formed on the substrate 901 on which the selection transistor 906 and others are formed. Next, a contact hole 915 penetrating the interlayer insulating film 914 and reaching to a line or an element formed on the substrate 901 (in FIG. 14, the drain region 903 in the selection transistor 906) is formed by a regular photolithography and a dry etching ((a) in FIG. 15). Next, a conductive material composing the conductive plug 916 (hereinafter simply referred to as the “conductive material 916”) is deposited in the contact hole 915 and on the interlayer insulating film 914 ((b) in FIG. 15), using the CVD method. Subsequently, the conductive material 916 deposited on the upper surface of the interlayer insulating film 914 is polished and removed by the chemical mechanical polishing (CMP) method ((c) in FIG. 15). With this process, the conductive plug 916 is formed in the contact hole 915. After that, the lower electrode 907, the variable resistance layer 908, and the upper electrode 909 are deposited in order on the upper surface of the conductive plug 916 and the interlayer insulating film 914 by the sputtering method ((d) in FIG. 15). Finally, the lower electrode 907, the variable resistance layer 908, and the upper electrode 909 are collectively processed by the dry etching method. As such, the variable resistance element 910 is formed ((e) in FIG. 15). Note that, the method for manufacturing the variable resistance element 910 described above is not only applicable to a case in which the variable resistance element 910 composes a 1T1R memory cell, but also to a case in which the variable resistance element 910 composes a 1D1R memory cell.

However, there is a problem of variation in the shape of the conventional variable resistance elements 910 caused by the manufacturing method. The following shall describe the cause of the variation in shape.

In the CMP process illustrated in (c) in FIG. 15, the conductive material 916 is polished and removed by over-polishing. The over-polishing refers to polishing for completely removing the conductive material 916 deposited on the interlayer insulating film 914. With this, it is possible to absorb variation in the thickness of the conductive material 916, and variation in the speed of polishing.

Usually, in the CMP process for the conductive material, the conductive material 916 is polished and removed such that the interlayer insulating film 914 remains. The polishing rate for the conductive material 916 is set to be faster than the polishing rate for the interlayer insulating film 914. However, due to the difference in the polishing rates, the upper part of the conductive material 916 filled in the contact hole 915 is slightly removed as well. As a result, the upper part of the conductive plug 916 is slightly depressed from the upper surface of the interlayer insulating film 914.

Furthermore, the over-polishing forms a depression referred to as a recess or erosion on the upper surface of the interlayer insulating film 914. Depending on the condition of the over-polishing, there is a case that the upper end surface of the conductive plug 916 protrudes from a bottom surface part of the recess or erosion. Even in this case, the upper end surface of the conductive plug 916 is slightly depressed from the upper surface of the interlayer insulating film 914.

(a) to (c) in FIG. 16 are process diagrams schematically illustrating an example of the method for manufacturing the conventional variable resistance element. (a) in FIG. 16 is a cross-sectional view after the conductive plug is formed in consideration of the recess caused by the over-polishing in the CMP process. (b) in FIG. 16 is a schematic description diagram of the erosion. (c) in FIG. 16 is a cross-sectional view after the conductive plug is formed in consideration of the influence of the recess and erosion in the CMP process.

(a) in FIG. 16 schematically illustrates a cross-sectional view of an element in which the recess is formed after the conductive plug 916 is formed. (b) in FIG. 16 schematically illustrates a cross-sectional view of the element in which the erosion is formed, disclosed in the patent literature 7: Japanese Unexamined Patent Application Publication No. 2002-343794. (c) in FIG. 16 schematically illustrates a cross-sectional view of the element in which both the recess and erosion are formed at the same time.

The recess is a depressed part on the surface of the interlayer insulating film 914 formed in the upper part of the contact hole 915 (FIG. 15(c), FIG. 16(a)). The recess is formed as follows. First, when the over-polishing is performed in the CMP process illustrated in (c) in FIG. 15, the upper part of the conductive material 916 filled in the contact hole 915 is slightly removed, as described above. With this, the interlayer insulating film 914 is partially exposed in the inner peripheral surface in the upper part of the contact hole 915. The exposed surface of the interlayer insulating film 914 is slightly removed as well at the time of over-polishing. Consequently, the shape of the interlayer insulating film 914 in the upper part of the contact hole 915 is depressed and tapered. This is referred to as a recess.

The erosion refers to a phenomenon in which the interlayer insulating film 914 which is not supposed to be polished is polished at the time of over-polishing with the conductive material 916 in the proximity of the region of fine lines such as the conductive plugs 916. As illustrated in the cross-sectional view in (b) in FIG. 16, the amount of polishing removed by the erosion differs depending on the density of the pattern in the fine line part. In the region in which the conductive plugs 916 are densely formed (the region on the left side in (b) in FIG. 16), a depressed part is formed on the surface of the interlayer insulating film 914 and the conductive plug 916 (illustrated as A in (b) in FIG. 16) by the erosion. In contrast, in a region where the conductive plugs are sparsely formed (the region on the right side in (b) in FIG. 16); the depression on the surface caused by the erosion is less likely to be formed. The variation in the amount of depressions in different regions due to the depressions on the surface caused by the erosion and (caused by the difference in the extent of erosion) results in the variation in the shape of the interlayer insulating film 914 and the variation in the height of the conductive plugs 916.

Furthermore as illustrated in (c) in FIG. 16, there is a case in which the recess and erosion are formed at the same time.

The variation in the shape of the interlayer insulating film 914 and the variation in the height of the conductive plugs 916 described above may cause variation in the result of subsequent processes (such as uneven thickness when depositing a film or defect in exposure during the photolithography process). This could be a cause of defect in the shape or characteristics of the lower electrode 907, the variable resistance layer 908, and the upper electrode 909 formed on the interlayer insulating film 914 and the conductive plugs 916.

More specifically, the variable resistance element 910 is driven by a current having a high current density flowing in the thickness direction of the lower electrode 907, the variable resistance layer 908, and the upper electrode 909 (the vertical direction in FIG. 14). Accordingly, reducing the variation in the shape is preferable in order to reduce the variation in the characteristics of the devices and to improve the characteristics and reliability of the device.

The patent literature 6 discloses an example in which the surface of the interlayer insulating film is planarized after the erosion is formed, and the depressed part in the interlayer insulating film caused by the erosion is removed in order to reduce flake-off or scratch on the electrode.

However, although the depressed part in the interlayer insulating film is planarized, the variation in the height of the conductive plugs caused by the erosion is not solved. Accordingly, the defect in the shape of the electrode or the variable resistance layer caused by the variation in the height of the conductive plugs is not solved.

The present invention has been conceived in order to solve the conventional problems described above, and it is an object of the present invention to provide a method for manufacturing a highly reliable variable resistance element having excellent characteristics by planarizing the upper surface of the interlayer insulating film and the upper surface of the lower electrode so as to reduce the variation in the characteristics of the variable resistance elements.

### Solution to Problem

In order to solve the conventional problem described above, the method for manufacturing the variable resistance element according to the present disclosure features forming an interlayer insulating film on a substrate; forming a contact hole in the interlayer insulating film; depositing a conductive material in the contact hole and on the interlayer insulating film; forming a conductive plug in the contact hole by removing the conductive material deposited on the interlayer insulating film; planarizing an upper surface of the interlayer insulating film after the conductive plug is formed; forming, on the interlayer insulating film and the conductive plug, a lower electrode layer electrically connected to the conductive plug; planarizing an upper surface of the lower electrode layer; forming, on the lower electrode layer, a variable resistance layer having a resistance value reversibly changes based on an application of an electric pulse; and forming an upper electrode layer on the variable resistance layer.

### Advantageous Effects of Invention

According to the method for manufacturing the variable resistance element, by planarizing the lower surface and the upper surface of the lower electrode, the variation in the characteristics of the variable resistance element can be reduced. Therefore, it is possible to obtain a highly reliable variable resistance element having excellent characteristics.

### BRIEF DESCRIPTION OF DRAWINGS

FIG. 1 is a flowchart illustrating an example of the method for manufacturing a variable resistance element according to the embodiment 1.

(a) to (e) in FIG. 2 are process diagrams schematically illustrating an example of the method for manufacturing the 1T1R memory cell according to the embodiment 1. (a) in FIG. 2 is a cross-sectional view of a substrate. (b) in FIG. 2 is a cross-sectional view after the interlayer insulating film is formed. (c) in FIG. 2 is a cross-sectional view after the contact hole is formed. (d) in FIG. 2 is a cross-sectional view after the contact hole is filled with a conductive material. (e) in FIG. 2 is a cross-sectional view after the conductive plug is formed.

(a) to (e) in FIG. 3 are process diagrams schematically illustrating an example of the method for manufacturing the 1T1R memory cell according to the embodiment 1. (a) in FIG. 3 is a cross-sectional view after the upper surface of the interlayer insulating layer is formed. (b) in FIG. 3 is a cross-sectional view after the lower electrode is formed. (c) in FIG. 3 is a cross-sectional view after the upper surface of the lower electrode is planarized. (d) in FIG. 3 is a cross-sectional view after the materials for the variable resistance layer and the upper electrode are formed. (e) in FIG. 3 is a cross-sectional view after the variable resistance element is formed.

FIG. 4 is a cross-sectional view schematically illustrating the configuration of the 1T1R memory cell according to the embodiment 1.

FIG. 5 illustrates the characteristics of the operation of the variable resistance element according to the embodiment 1.

(a) in FIG. 6 is an image taken under an atomic force microscope (AFM) showing unevenness on surfaces of the interlayer insulating film and conductive plugs observed in the variable resistance element according to the embodiment 1 after the conductive plugs are formed. (b) in FIG. 6 is a chart illustrating the unevenness on the surface in a cross section in the direction of the arrows in line VI-VI in (a) in FIG. 6.

(a) in FIG. 7 is an image taken under an atomic force microscope (AFM) showing unevenness on surfaces of the interlayer insulating film and conductive plugs observed in the variable resistance element according to the embodiment 1 after an isolated conductive plug is formed. (b) in FIG. 7 is a chart illustrating the unevenness on the surface in a cross section in the direction of the arrows in line VII-VII in (a) in FIG. 7.

(a) in FIG. 8 is an image taken under an atomic force microscope (AFM) showing unevenness on surfaces of the interlayer insulating film and conductive plugs observed in a region in which densely provided conductive plugs are present in the variable resistance element according to the embodiment 1 after the surface of the interlayer insulating film is planarized. (b) in FIG. 8 is a chart illustrating the unevenness on the surface in a cross section in the direction of the arrows in line VIII-VIII in (a) in FIG. 8.

(a) in FIG. 9 is an image taken under an atomic force microscope (AFM) showing unevenness on surfaces of the interlayer insulating film and conductive plugs observed in a region in which the isolated conductive plug is present in the variable resistance element according to the embodiment 1 after the surface of the interlayer insulating film is planarized. (b) in FIG. 9 is a chart illustrating the unevenness on the surface in a cross section in the direction of the arrows in line IX-IX in (a) in FIG. 9.

FIG. 10 is a cross-sectional view schematically illustrating the configuration of a 1T1R memory cell according to the embodiment 2.

FIG. 11 is a flowchart illustrating an example of the method for manufacturing a variable resistance element according to the embodiment 2.

(a) and (b) in FIG. 12 are cross-sectional views schematically illustrating the configurations of 1D1R memory cells according to the embodiment 3.

FIG. 13 is a flowchart illustrating an example of the method for manufacturing a variable resistance element according to the embodiment 3.

FIG. 14 is a cross-sectional view schematically illustrating the configuration of a conventional 1T1R memory cell having a variable resistance element.

(a) to (e) in FIG. 15 are process diagrams schematically illustrating an example of the method for manufacturing the conventional 1T1R memory cell. (a) in FIG. 15 is a cross-sectional view after the contact hole is formed. (b) in FIG. 15 is a cross-sectional view after the contact hole is filled with a conductive material. (c) in FIG. 15 is a cross-sectional view after the conductive plug is formed. (d) in FIG. 15 is a cross-sectional view after the materials for the upper electrode is formed. (e) in FIG. 15 is a cross-sectional view after the variable resistance element is formed.

(a) to (c) in FIG. 16 are process diagrams schematically illustrating an example of the method for manufacturing the conventional variable resistance element. (a) in FIG. 16 is a cross-sectional view after the conductive plug is formed in consideration of the recess caused by the over-polishing in the CMP process. (b) in FIG. 16 is a schematic description diagram of the erosion. (c) in FIG. 16 is a cross-sectional view after the conductive plug is formed in consideration of the effect of the recess and erosion in the CMP process.

### DESCRIPTION OF EMBODIMENTS

The following shall describe embodiments of the present invention with reference to the drawings.

### Embodiment 1

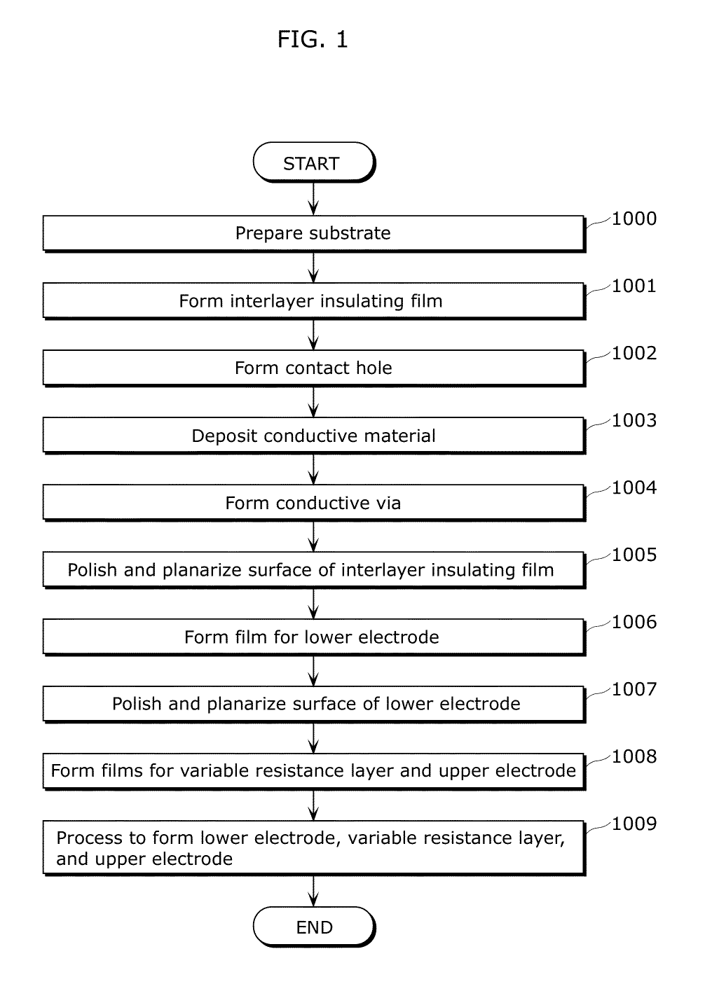

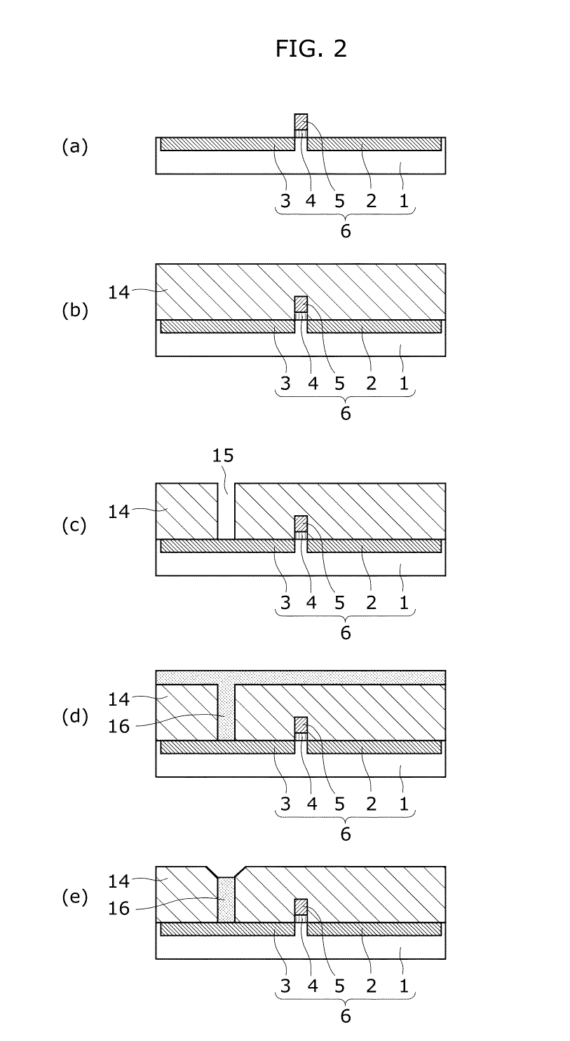

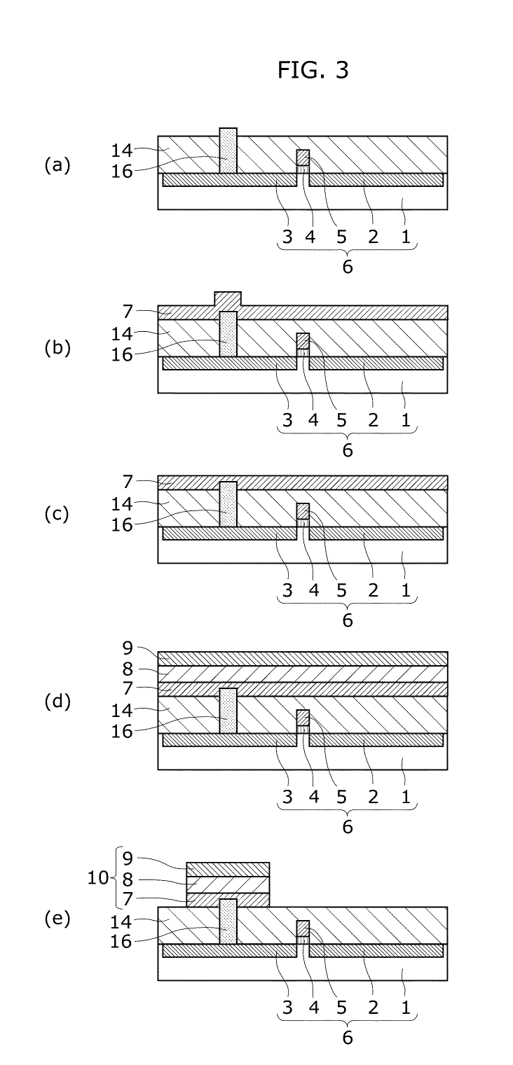

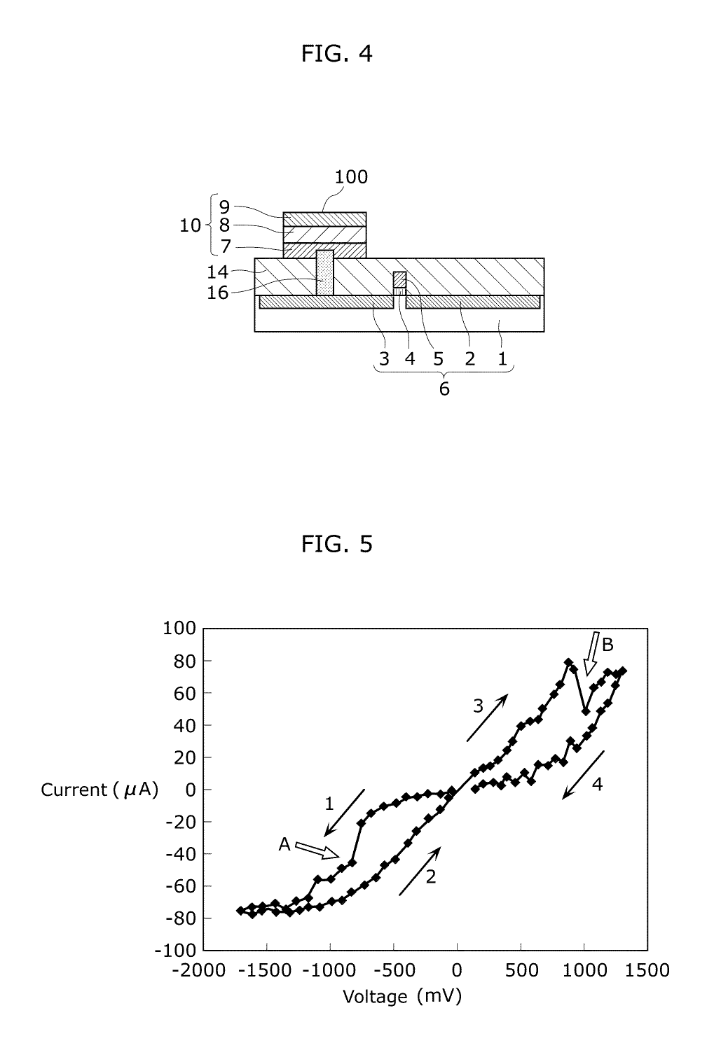

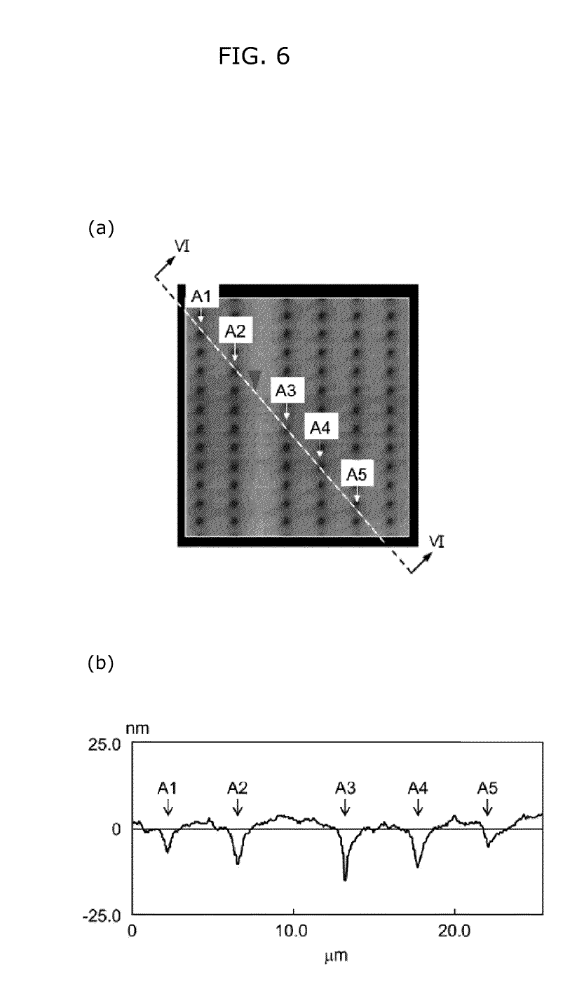

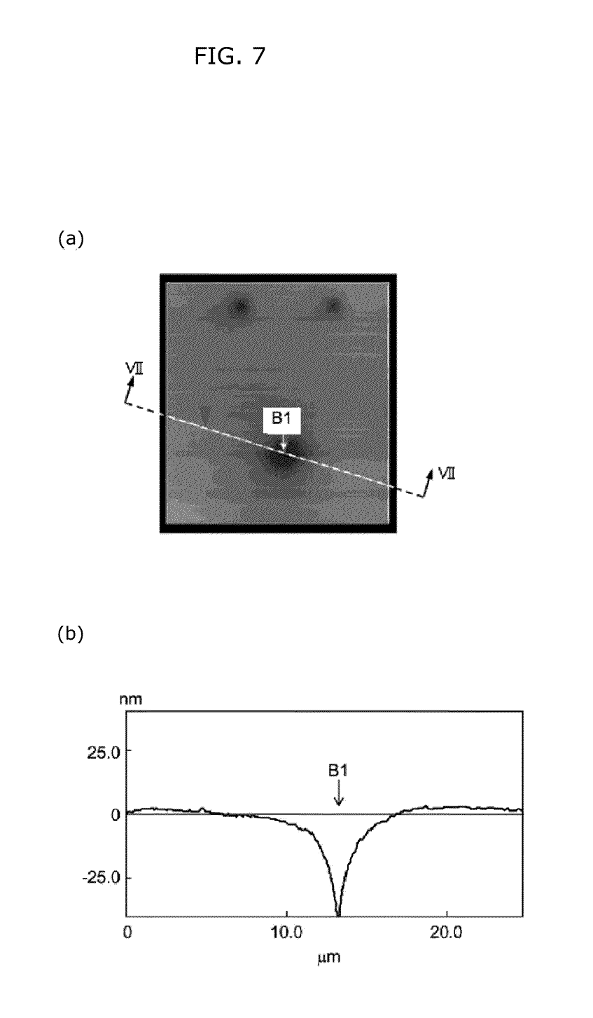

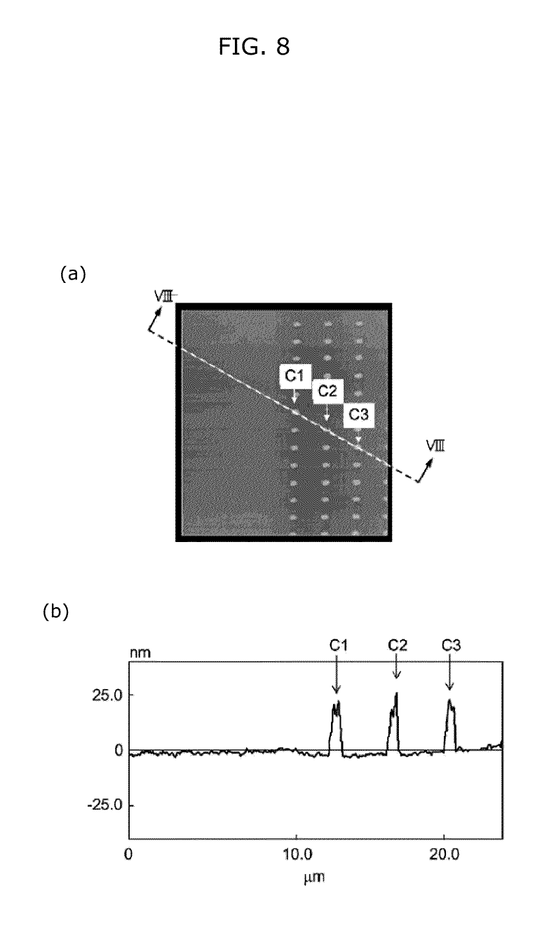

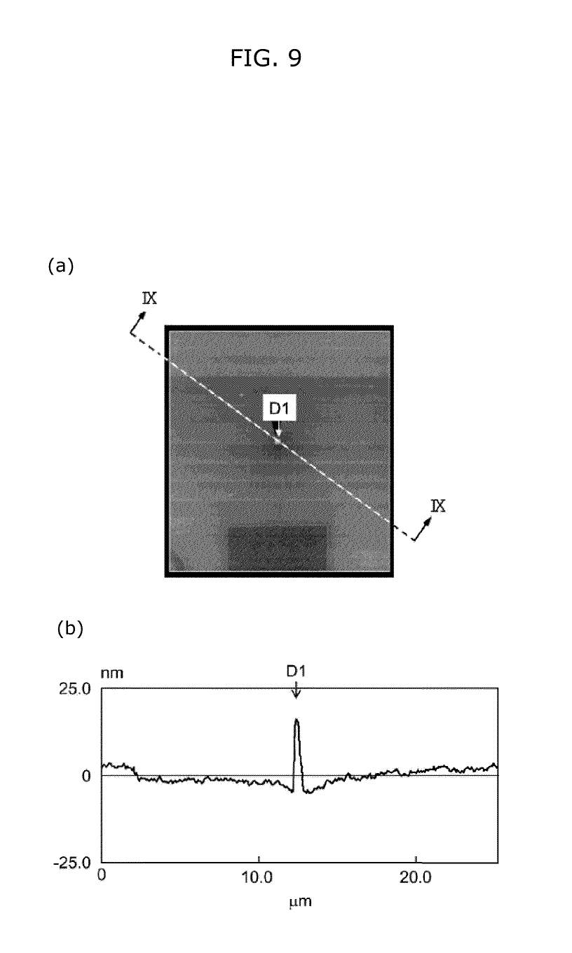

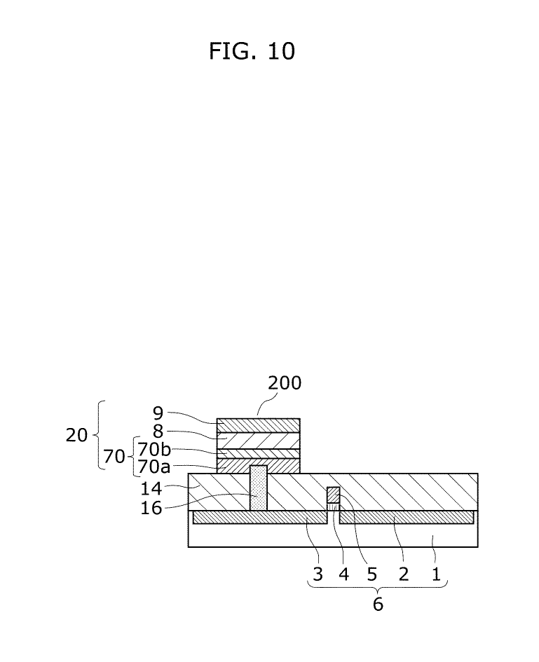

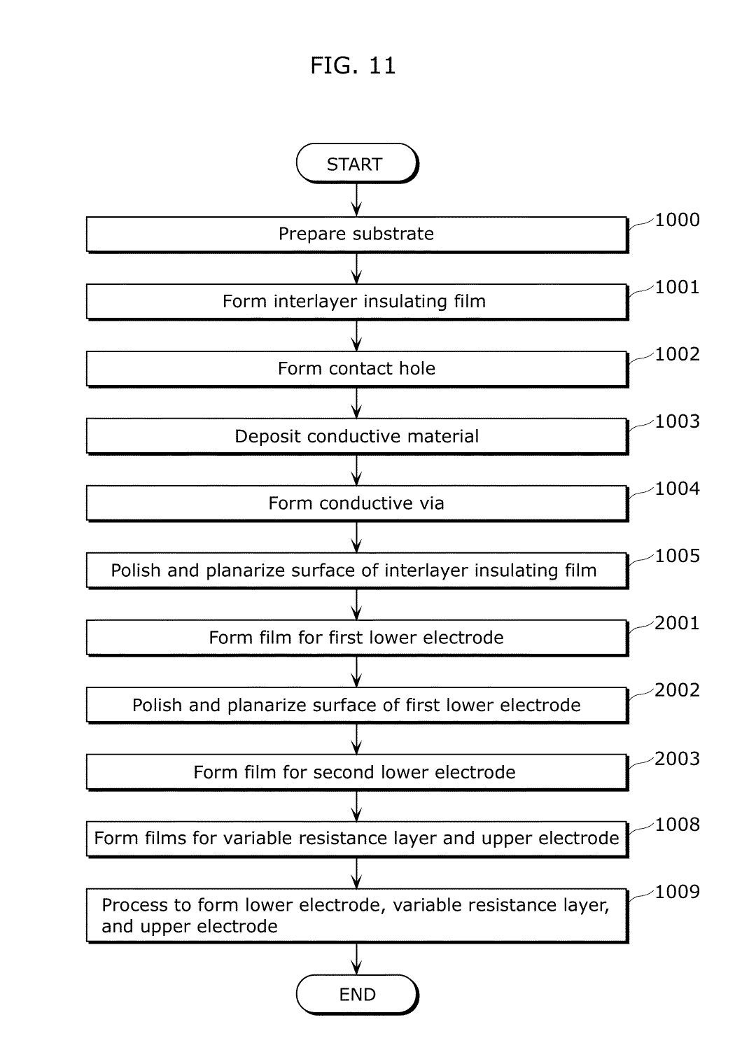

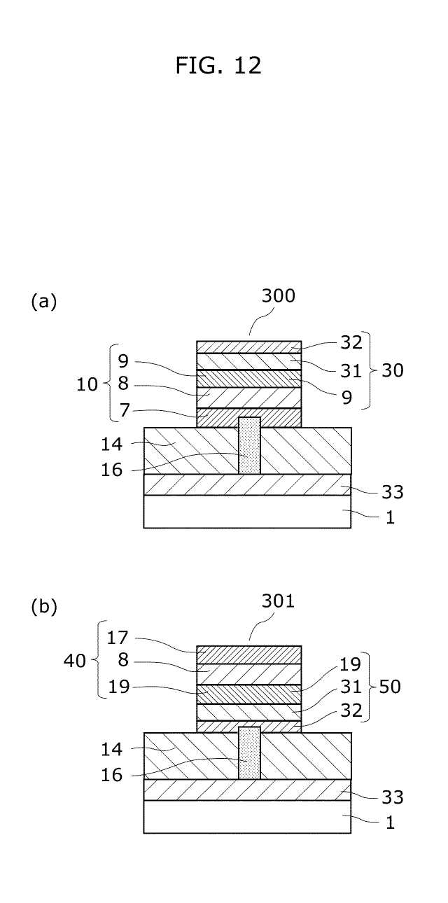

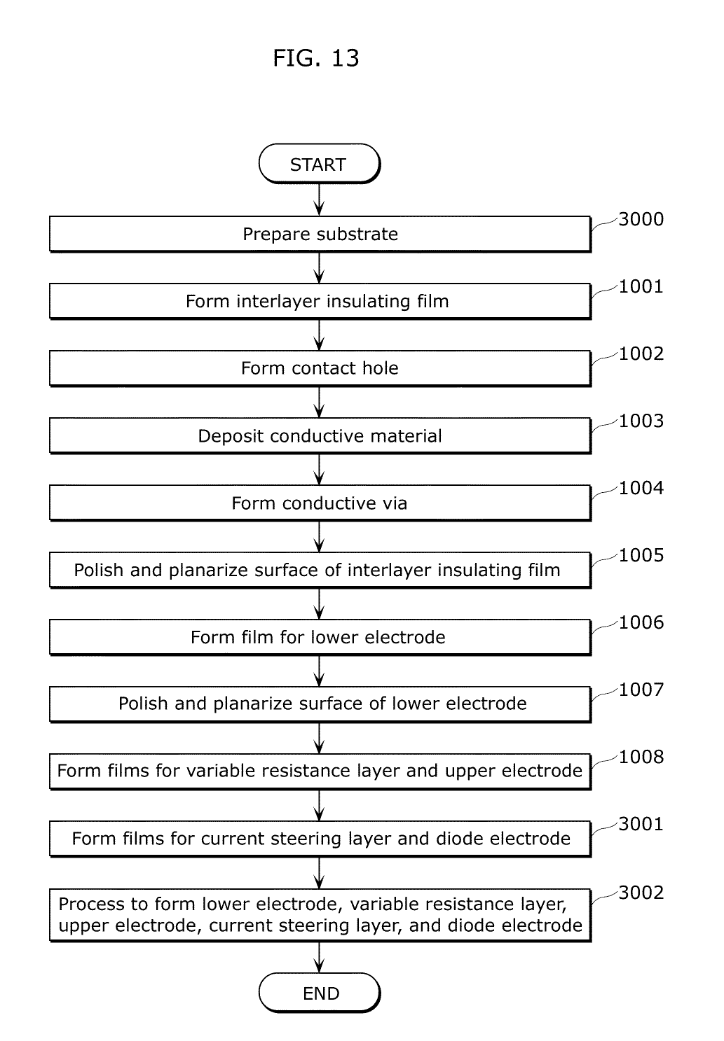

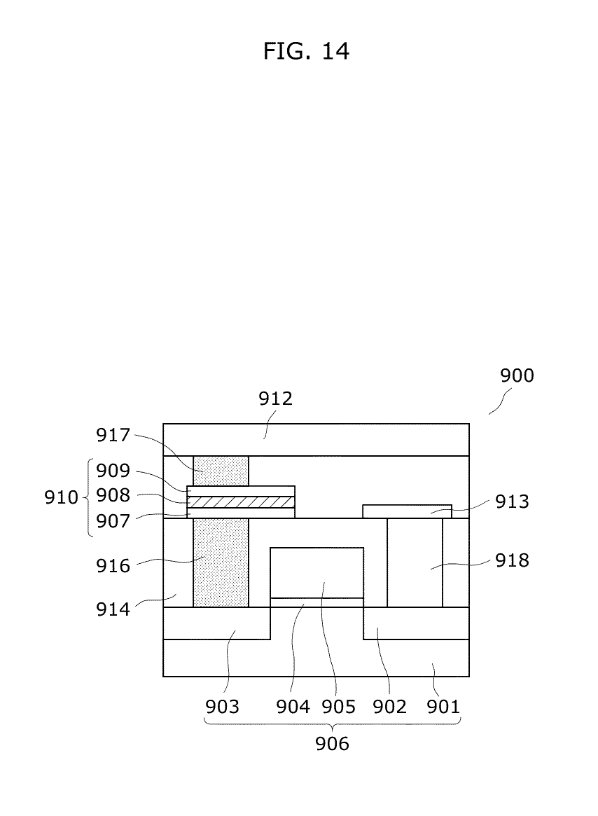

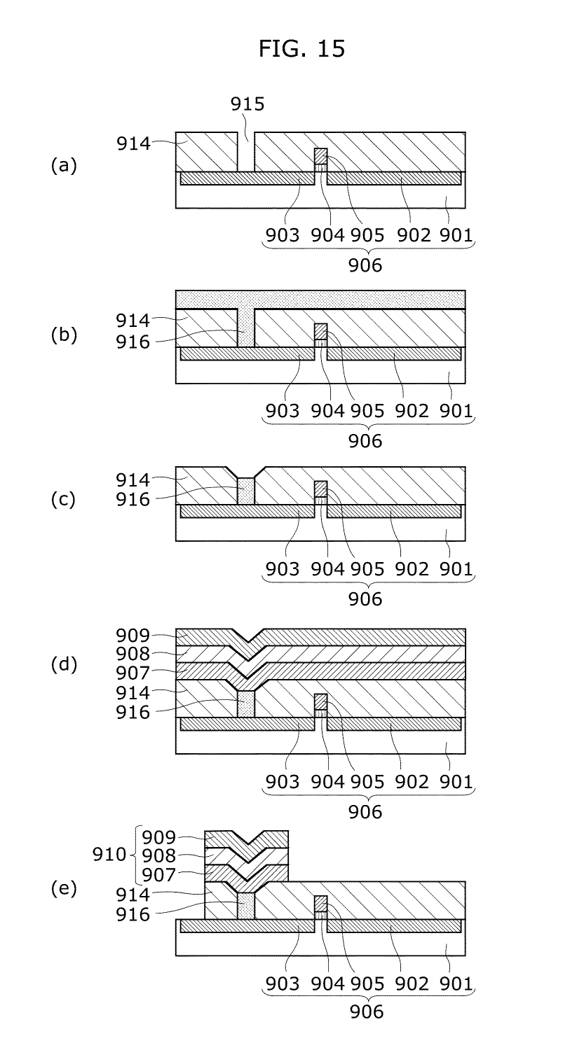

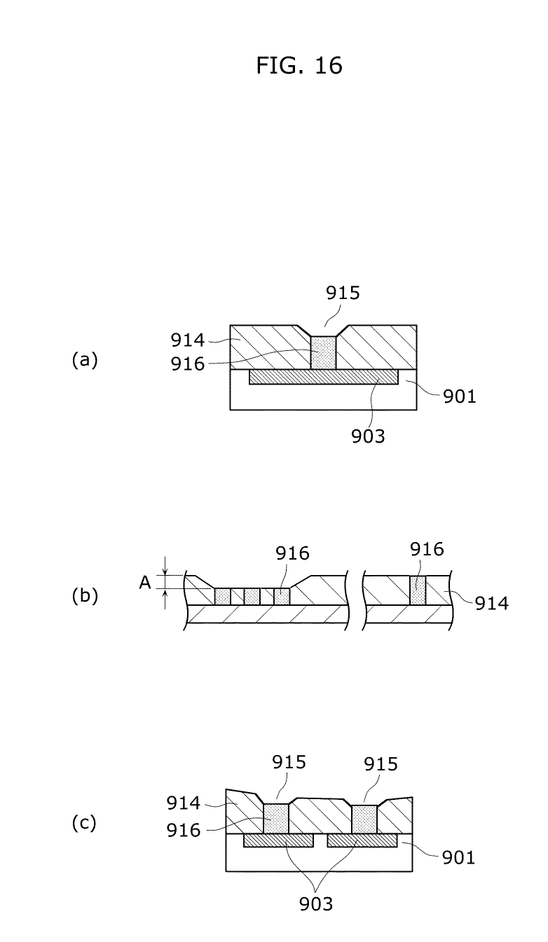

An example of a method for manufacturing a variable resistance element according to the embodiment 1 shall be described with reference to the flowchart in FIG. 1 and the process diagrams in (a) to (e) in FIG. 2 and (a) to (e) in FIG. 3.

FIG. 1 is a flowchart illustrating an example of the method for manufacturing the variable resistance element according to the embodiment 1.

(a) to (e) in FIG. 2 are process diagrams schematically illustrating an example of the method for manufacturing the 1T1R memory cell according to the embodiment 1. (a) in FIG. 2 is a cross-sectional view of the substrate. (b) in FIG. 2 is a cross-sectional view after the interlayer insulating film is formed. (c) in FIG. 2 is a cross-sectional view after the contact hole is formed. (d) in FIG. 2 is a cross-sectional view after the contact hole is filled with the conductive material. (e) in FIG. 2 is a cross-sectional view after the conductive plug is formed.

(a) to (e) in FIG. 3 are process diagrams schematically illustrating another example of the method for manufacturing the 1T1R memory cell according to the embodiment 1. (a) in FIG. 3 is a cross-sectional view after the upper surface of the interlayer insulating film is planarized. (b) in FIG. 3 is a cross-sectional view after the film for the lower electrode is formed. (c) in FIG. 3 is a cross-sectional view after the upper surface of the lower electrode is planarized. (d) in FIG. 3 is a cross-sectional view after the materials for the variable resistance layer and the upper electrode are formed. (e) in FIG. 3 is a cross-sectional view after the variable resistance element is formed.

The process 1000 to the process 1004 in FIG. 1 correspond to (a) to (e) in FIG. 2, respectively. The process 1005 to the process 1009 in FIG. 1 correspond to (a) to (e) in FIG. 3, respectively. Note that, in the flowchart in FIG. 1, a series of processes assigned with the process numbers is illustrated. However, the process numbers are merely for simplifying and clarifying the description. The process numbers do not necessarily indicate the order of the processes. Note that, it is possible to skip a part of the processes, or to perform more than one process at the same time, and it is not necessary to strictly maintain the order. Although (a) to (e) in FIG. 2 and (a) to (e) in FIG. 3 are process diagrams for illustrating the method for manufacturing the 1T1R memory cell 100 illustrated in FIG. 4, the forming process of the variable resistance element 10 is not limited to a 1T1R memory cell. As described later, the method for manufacturing the variable resistance element 10 according to the embodiment 1 is applicable to the manufacturing of the variable resistance element 10 composing a 1D1R memory cell or others.

The following shall describe the method for manufacturing the variable resistance element 10 according to the embodiment 1 following the flowchart in FIG. 1 and with reference to (a) to (e) in FIG. 2 and (a) to (e) in FIG. 3.

A substrate is prepared in the process 1000. When manufacturing a 1T1R memory cell, a selection transistor 6 formed on the substrate 1, including a source region 2, a drain region 3, a gate oxide film 4, and a gate electrode 5 formed according to the known method, as illustrated in (a) in FIG. 2 may be used. Note that, the substrate 1 may have a configuration electrically connected to the variable resistance element 10 formed in a subsequent process. Accordingly, the configuration of the substrate 1 is not limited to this example.

First, in the process 1001, an interlayer insulating film 14 is deposited on the main surface of the substrate 1 using the CVD method or others ((b) in FIG. 2). The interlayer insulating film 14 comprises a various insulating material. For example, the interlayer insulating film 14 comprises a silicon oxide film (hereafter referred to as P-TEOS) using tetraethyl orthosilicate (TEOS) as the material and formed by the plasma CVD method.

Next, in the process 1002, the contact hole 15 penetrating the interlayer insulating film 14 and reaching inside the substrate (lines, diffusion layer, and others inside) is formed by dry etching or others. (c) in FIG. 2 illustrates a cross-sectional view after the contact hole 15 penetrating the interlayer insulating film 14 and reaching the drain region 3 in the selection transistor 6 is formed.

Next, in the process 1003, the contact hole 15 is filled with a conductive material which will be the conductive plug 16 in the subsequent process 1004 (hereafter simply referred to as the “conductive material 16”) by the sputtering method, the CVD method, or others. Here, as illustrated in (d) in FIG. 2, not only inside the conduct hole 15, but also the entire main surface of the substrate (covered with the interlayer insulating film 14) is covered with the conductive material 16. Various metal and conductive compounds are used for the conductive material 16. Tungsten (W) is preferably used for the conductive material 16. When tungsten (W) is used as the conductive material 16, first, metal such as titanium (Ti), titanium nitride (TiN) or others is usually deposited by the CVD method, the sputtering method, or others. Subsequently, tungsten (W) is deposited thereon using the CVD method.

Next, in the process 1004, the conductive material 16 (and the adhesion layer) covering the interlayer insulating film 14 on the main surface of the substrate 1 is polished and removed, leaving the conductive material 16 (and the adhesion layer) in the contact hole 15, using the CMP method. With this process, the conductive plug 16 is formed in the contact hole 15. The slurry used for the CMP process in the process 1004 preferably includes abrasive such as alumina or silica and oxidant for oxidizing the conductive material 16. For example, the slurry for polishing tungsten (W) preferably contains alumina at a concentration of 1 to 6 wt %, and has pH of 4 or lower. The oxidant contained in the slurry oxidizes the conductive material 16. The abrasive contained in the slurry polishes the conductive material 16 weakened by oxidation, through chemical and mechanical actions.

In the process 1004, over-polishing is performed such that no conductive material 16 (and the adhesion layer) remains on the interlayer insulating film 14. Here, the conductive material 16 (and the adhesion layer) is polished and removed, leaving the interlayer insulating film 14. The polishing rate for the conductive material 16 is preferably faster than the polishing rate of the interlayer insulating film 14. For example, as the condition for polishing the conductive material 16 comprised of tungsten (W) deposited on the interlayer insulating film 14 composed of P-TEOS, the rate for polishing tungsten may be 190 nm/minute, and the rate for polishing P-TEOS may be 12.3 nm/minute. However, due to the difference in the polishing rates, the upper part of the conductive plug 16 in the contact hole 15 is removed, and the conductive plug 16 is slightly depressed from the upper surface of the interlayer insulating film 14 ((e) in FIG. 2). In addition, the surface of the interlayer insulating film 14 above the conductive plug 16 is removed in a tapered shape, forming a recess ((e) in FIG. 2). (a) to (e) in FIG. 2 and (a) to (e) in FIG. 3 are for illustrating the formation of a single conductive plug 16. However, in the actual device manufacturing, erosion is formed depending on the density of the fine line part in addition to the over-polishing and the recess described above. Due to the over-polishing, recess, and erosion, the height of the conductive plug 16 formed in the contact hole 15 varies, forming a depressed part on the upper surface of the interlayer insulating film 14.

Next, the interlayer insulating film 14 is planarized by the polishing using the CMP method in the process 1005. Almost all of the depression in the interlayer insulating film 14 (caused by the recess and erosion) formed in the preceding process 1004 is solved. It is preferable that the slurry used for the CMP process in the process 1005 includes abrasives such as alumina, silica, or ceria, and has alkaline or neutral property. It is preferable that the slurry for the insulating film contains silica having an average grain size of 0.1 to 0.2 μm at a concentration of approximately 13 wt %, and pH in a range from 7 to 11. For example, when the interlayer insulating film 14 is an oxide film such as P-TEOS, increasing pH of the solvent makes the removal easier.

Unlike the polishing of the conductive material 16, neutral or alkaline slurry is used for polishing the interlayer insulating film 14. Accordingly, the conductive material 16 is not weakened by the oxidization, and the conductive material 16 is barely removed by polishing. When the conductive plug 16 comprises tungsten (W), the conductive plug 16 is barely removed by polishing under the polishing condition. Accordingly, it is possible to reduce the variation in the amount of depression of the interlayer insulating film 14 caused by the over-polishing, recess and erosion.

(a) in FIG. 3 illustrates that the upper surface of the interlayer insulating film 14 is planarized by the polishing, and the upper part of the conductive plug 16 protrudes from the upper surface of the interlayer insulating film 14 accordingly. The CMP can be used as the polishing method, for example. It is necessary that the protruding part of the conductive plug 16 protrudes to an extent sufficient to solve the depression of the interlayer insulating film 14. However, it is preferable that the amount of protrusion (the height from the upper surface of the interlayer insulating film 14 to the top of the conductive plug 16) is not large. This is because of the following two reasons.

The first reason is related to the processing of the lower electrode 7. The lower electrode 7 is formed on the protruding conductive plug 16 in a subsequent process 1006. Here, it is preferable that the lower electrode 7 is formed with a thickness which allows the conductive plug 16 not to penetrate the lower electrode 7. Accordingly, the thickness of the lower electrode 7 is adjusted greater than or equal to the amount of protrusion of the conductive plug 16. Accordingly, the larger the amount of protrusion of the conductive plug 16 is, the greater the thickness of the lower electrode 7 becomes. However, in consideration of the processing of the lower electrode 7 in the subsequent process 1009, it is preferable that the lower electrode 7 is not too thick. Accordingly, it is preferable that the protruding part of the conductive plug 16 is not too large either.

The second reason is related to the mechanical strength of the conductive plug 16. When polishing and planarizing the interlayer insulating film 14 in the process 1005, the conductive plug 16 receives physical or mechanical shock. Here, if the conductive plug 16 is polished with a large amount of protrusion, there is a possibility that the conductive plug 16 is deformed (bent, chipped, or others). As a result, there is a possibility that the deformation would result in the contact defect. Accordingly, it is preferable that the amount of protrusion in the conductive plug 16 is limited to a level that the conductive plug 16 is not likely to receive an intense mechanical shock.

Note that, the process 1005 is not limited to the CMP method. As another method for planarizing the upper surface of the interlayer insulating film 14, the resist is formed on the entire main surface of the substrate 1, and the entire surface may be etched back, for example. However, it is necessary to control the process such that all of the conductive plugs 16 protrude from the upper surface of the interlayer insulating film 14 and the amount of the protrusion of the conductive plug 16 is not excessive.

Next, the lower electrode 7 is formed on the interlayer insulating film 14 and the conductive plug 16 in the process 1006 using the CVD method, the sputtering method, or others. Here, since the interlayer insulating film 14 is planarized in the preceding process 1005, the upper surface and the lower surface of the lower electrode 7 formed on the interlayer insulating film 14 are flat, and the lower electrode 7 is formed to have an even thickness in the thickness direction. However, the upper surface of the lower electrode 7 formed on the conductive plug 16 is formed along the protruding conductive plug 16 formed in the preceding process 1005. Accordingly, the upper surface of the lower electrode 7 has a protruding shape ((b) in FIG. 3).

Next, in the process 1007, the protruding shape on the upper surface of the lower electrode 7 formed in the preceding process 1006 is polished by the CMP method. With this, as illustrated in (c) in FIG. 3, the lower electrode 7 having a flat surface is obtained. It is preferable that the upper surface of the lower electrode 7 after polishing is clean, in consideration of the process for forming the variable resistance layer 8 on the lower electrode 7 in the subsequent process 1008.

The lower electrode 7 is comprised of various metal materials or conductive compounds. It is preferable that the lower electrode 7 is comprised of tungsten (W), titanium (Ti) or a compound of tungsten or titanium (tungsten nitride (WN), titanium nitride (TiN) or others). Since the materials used for the polishing target of the CMP process in the preceding process 1004 can be used as the material. Accordingly, when the same material is used, there is an advantage that the polishing condition in the preceding process 1004 can be used for the materials as well. Alternatively, it is preferable that the lower electrode 7 comprises tantalum (Ta) or a compound of tantalum (tantalum nitride (TaN) or others). Since the materials are materials to be the polishing target in a CMP process for forming general copper lines for manufacturing devices. Accordingly, there is an advantage that the polishing conditions for the materials can be used as well. Furthermore, tungsten (W), titanium (Ti), and tantalum (Ta) are known as refractory metals, and highly resistant to electromigration. Accordingly, using these materials for the lower electrode 7 in the variable resistance element 10 usually driven by flow of current with a high current density (greater than or equal to 10000 A/cm²) is desirable in terms of characteristics and stability of the device.

Unlike the CMP process for the regular conductive material 16 as in the process 1004, it is necessary to control the thickness when performing polishing in the CMP process in the process 1007. For example, in the CMP process in the process 1004, the conductive material 16 (and the adhesion layer) is polished and removed, and the polishing ends when the interlayer insulating film 14 is exposed. In contrast, in the process 1007, it is necessary to finish the polishing when the upper surface of the lower electrode 7 is flat and the thickness of the lower electrode 7 is in a predetermined value. Accordingly, when performing the polishing in the process 1007, it is necessary to determine the end point of the polishing while monitoring the polishing speed of the material used for the lower electrode 7 and measuring the thickness of the material for the lower electrode 7 on the interlayer insulating film 14 (measuring the thickness of the remaining film after polishing).

In consideration of the process on the lower electrode 7 in the subsequent process 1009, it is preferable that the remaining film of the lower electrode 7 after the process 1007 is not too thick. More specifically, it is preferable that the thickness of the lower electrode 7 immediately above the conductive plug 16 is controlled to be in a range from approximately 20 to 50 nm.

Note that, the process 1007 is not limited to the CMP method. As another method for planarizing the upper surface of the lower electrode 7, the resist is formed on the entire main surface of the substrate 1, and the entire surface is etched back, for example. However, it is necessary to smooth the upper surface of the lower electrode 7 across the entire main surface of the substrate 1.

Next, in the process 1008, the variable resistance layer 8 and the upper electrode 9 are formed in order on the lower electrode 7, using the CVD method, the sputtering method, or others ((d) in FIG. 3). Since the upper surface of the lower electrode 7 is smoothed in the preceding process 1007, the variable resistance layer 8 and the upper electrode 9 stacked thereon are formed flat.

As the material for the variable resistance layer 8, perovskite metal oxide, oxide of main group metal or transition metal may be used. More specifically, PCMO (Pr₁₋ₓCaₓMnO₃ (0<x<1.0)), titanium oxide (TiOₓ (0<x<2.0)), nickel oxide (NiOₓ (0<x<1.0)), iron oxide (FeOₓ (0<x<1.5)), copper oxide (CuOₓ (0<x<2.0)), aluminum oxide (AlOₓ (0<x<1.5)), tantalum oxide (TaOₓ (0<x<2.5)), zirconium oxide (ZrOₓ (0<x<2.0)), hafnium oxide (HfOₓ (0<x<2.0)) or others, a substitute of these materials, or a mixture or stacked structure of these materials. These materials are oxygen-deficient oxide having a smaller amount of oxygen than a stoichiometric composition.

Alternatively, using the group of materials described above, the variable resistance layer 8 may include two layers, which is a stacked structure comprising a metal oxide which is a low resistance layer and another metal oxide which is a high resistance layer. In this case, by controlling the thickness of the high resistance layer, stable variable resistance characteristics with small variation in the initial resistance can be achieved. For example, when tantalum oxide TaOₓ (0<x<2.5) is used as the variable resistance layer 8, it is preferable to have a stacked structure having a layer comprising a first tantalum oxide TaOₓ (note that 0.8≦x≦1.9) and a layer comprising a second tantalum oxide TaO_{y} (note that 2.1≦y≦2.5, and the thickness is in a range from 1 nm to 8 nm). In this case, the resistivity of TaOₓ is lower, and the TaOₓ layer is the low resistance layer. The resistivity of TaO_{y} is higher, and the TaO_{y} layer is the high resistance layer. This structure allows a variable resistance element to have high-speed and reversibly stable rewriting characteristics and excellent resistance value retention characteristics. Furthermore, the effects are not limited to the case in which tantalum oxide is used. For example, the stacked structure may be a stacked structure of zirconium oxides (ZrOₓ (0.9≦x≦1.4) as the low resistance layer and ZrO_{y} (1.9<y<2.0) as the high resistance layer stacked, and the thickness of ZrO_{y} is in a range from 1 nm to 5 nm), or a stacked structure of hafnium oxides (HfOₓ (0.9≦x≦1.6) as the low resistance layer and HfO_{y} (1.8<y<2.0) as the high resistance layer stacked, and the thickness of HfO_{y} is in a range from 3 nm to 4 nm).

Note that, different transition metals may be used as a transition metal comprising the metal oxide of the low resistance layer and a transition metal comprising the metal oxide of the high resistance layer. In this case, the transition metal oxide in the high resistance layer has an oxygen deficiency lower than the transition metal oxide in the low resistance layer. The oxygen deficiency refers to a ratio of deficient oxygen compared to the amount of oxygen composing a stoichiometric oxide of each of the transition metals. For example, when the transition metal is tantalum (Ta), the composition of the stoichiometric oxide is Ta₂O₅, which can be represented as TaO_{2.5}. The oxygen deficiency of TaO_{2.5} is 0%. The oxygen deficiency of tantalum oxide having a composition of TaO_{1.5} is oxygen deficiency=(2.5−1.5)/2.5=40%. The oxygen content percentage of Ta₂O₅ is a ratio of oxygen in the total number of atoms (O/(Ta+O)), and is 71.4 atm %. Accordingly, the oxygen content percentage of an oxygen-deficient tantalum oxide is greater than 0 and smaller than 71.4 atm %.

With this structure, a larger part of voltage applied between the lower electrode 7 and the upper electrode 9 at the time of resistance change is distributed to the high resistance layer in the variable resistance layer 8, making the high resistance layer in the variable resistance layer 8 more susceptible to an oxidation-reduction reaction. Alternatively, when different transition metals are used for the high resistance layer and the low resistance layer in the variable resistance layer 8, it is preferable that the normal electrode potential of the transition metal in the high resistance layer is smaller than the normal electrode potential of the transition metal in the low resistance layer. It is assumed that the resistance change phenomenon occurs when the resistance value of a fine filament (conductive path) formed in the transition metal oxide layer in the high resistance layer having high resistance changes due to an oxidation-reduction reaction in the fine filament. For example, using an oxygen deficient tantalum oxide as the transition metal oxide in the low resistance layer and a titanium oxide (TiO₂) as the transmission metal oxide in the high resistance layer allows a stable resistance change operation. Titanium (Normal electrode potential=−1.63 eV) is a material having a normal electrode potential smaller than tantalum (normal electrode potential=−0.6 eV). The larger the value of the normal electrode potential is, the less likely the material is to be oxidized. By using, as the transition metal oxide for the high resistance layer, the oxide of a transitional metal having a smaller normal electrode potential than the transition metal oxide used as the low resistance layer, the oxidation-reduction reaction is more likely to occur in the transition metal oxide in the high resistance layer.

The upper electrode 9 comprises various metal materials or conductive compounds. For example, when a tantalum oxide (TaOₓ) is used for the variable resistance layer 8, the rewriting characteristics of the variable resistance element 10 is reversibly stable by comprising one of the lower electrode 7 or the upper electrode 9 by a material having a higher normal electrode potential than Ta and is less likely to be oxidized (a material in which the resistance change is more likely to occur), and by comprising the other of the lower electrode 7 or the upper electrode 9 by a material having a lower normal electrode potential than the upper electrode (a material in which the resistance change is less likely to occur). More specifically, when tantalum oxide (TaOₓ) is used for the variable resistance layer 8, examples of materials in which the resistance change is likely to occur include precious metals such as platinum (Pt), iridium (Ir), palladium (Pd) and others, while examples of materials in which the resistance change is less likely to occur include aluminum (Al), titanium (Ti), tantalum nitride (TaN), and others. Accordingly, it is preferable to select the upper electrode 9 to satisfy the combinations described above.

It is assumed that the resistance changing phenomenon in the variable resistance layer 8 in the stacked structure of the materials described above occurs by an oxidation-reduction reaction in a fine filament (conductive path) formed in the transition metal oxide in the high resistance layer, causing a change in the resistance value of the high resistance layer. More specifically, it is assumed that the resistance in the fine filament increases by an oxidation reaction in the fine filament formed in the high resistance layer by the oxygen ions in the variable resistance layer 8 attracted to the high resistance layer side when a positive voltage is applied on one of the lower electrode 7 and the upper electrode 9 in reference to the other electrode. Note that the one of the lower electrode 7 and the upper electrode 9 is connected to the high resistance layer in the variable resistance layer 8. In contrast, it is assumed that the resistance in the fine filament reduces by a reduction reaction in the fine filament formed in the high resistance layer by the oxygen ions in the high resistance layer pushed away toward the low resistance layer, when a negative voltage is applied on one of the lower electrode 7 and the upper electrode 9 in reference to the other electrode. Note that the one of the lower electrode 7 and the upper electrode 9 is connected to the high resistance layer in the variable resistance layer 8.

Among the lower electrode 7 and the upper electrode 9, the one electrode connected to the high resistance layer in the variable resistance layer 8 is composed of a material such as platinum (Pt) and iridium (Ir), having a normal electrode potential higher than the transition metal comprising the high resistance layer in the variable resistance layer 8 and the material comprising the other electrode. This configuration allows selective oxidation-reduction reaction in one of the lower electrode 7 or the upper electrode 9 connected to the high resistance layer in the variable resistance layer 8 and in the variable resistance layer 8 in the proximity of the interface with the high resistance layer in the variable resistance layer 8, allowing stable resistance change.

Finally, in the process 1009, the stacked structure is processed by dry etching or others to form the lower electrode 7, the variable resistance layer 8, and the upper electrode 9. With this process, the variable resistance element 10 is formed as illustrated in (e) in FIG. 3. Here, it is assumed that the stacked structure including the lower electrode 7, the variable resistance layer 8, and the upper electrode 9 is collectively processed using the dry etching. However, it is not limited to this example, and each layer of the lower electrode 7, the variable resistance layer 8, and the upper electrode 9 may be individually processed using multiple photo masks, for example.

The 1T1R memory cell 100 illustrated in FIG. 4 is manufactured in the processes described above.

FIG. 4 is a cross-sectional view schematically illustrating the configuration of a 1T1R memory cell 100 according to the embodiment 1 and manufactured by the manufacturing method according to the embodiment 1 described above. In the memory cell 100, the variable resistance element 10 is connected electrically in series with the selection transistor 6. The variable resistance element 10 includes the variable resistance layer 8 having a resistance value reversibly changes based on the application of electrical pulse disposed between the lower electrode 7 and the upper electrode 9. The conductive plug 16 formed in the interlayer insulating film 14 electrically connects the lower electrode 7 and the drain region 3 in the selection transistor 6.

The lower electrode 7 has a flat upper surface and a flat lower surface (except for the interface between the lower electrode 7 and the upper surface of the conductive plug). This configuration improves characteristics and reliability of the variable resistance element 10, reducing the variation in the characteristics.

The upper part of the conductive plug 16 protrudes from the upper surface of the interlayer insulating film 14. Since the protruding part in the upper part of the conductive plug 16 has a junction with the lower electrode 7, the area in which the lower electrode 7 and the conductive plug 16 are in contact with each other can be increased compared to a conventional element. Accordingly, it is possible to reduce the electrical resistance on the contact surface, reduce the electric loss, and suppress the Joule heat generated. Furthermore, if the contact area of the lower electrode 7 and the conductive plug 16 increases, it is possible to reduce heat resistance on the contact surface further. When the heat resistance is small, the Joule heat generated in the lower electrode 7 or the conductive plug 16 when current flows is effectively radiated. As a result, the thermal stress on the lower electrode 7, the conductive plug 16, or others due to the Joule heat is reduced. Accordingly, the shape in which the protruding part of the conductive plug 16 is bonded with the lower electrode 7 is a preferable configuration in terms of the thermal characteristics, electric characteristics, and reliability. In particular, the effect on the contact surface is important for a variable resistance element 10 usually driven by current having a high current density (greater than or equal to 10000 A/cm²).

Furthermore, the shape in which the upper surface of the conductive plug 16 protrudes and the lower electrode 7 covers the protruding part of the conductive plug 16 increases the adhesion between the conductive plug 16 and the lower electrode 7. In particular, in the CMP process in which a physical force is exerted in the horizontal direction, abrasion was likely to occur at the interface between the plug and the electrode. However, according to the structure of the present invention, the protruding part in the conductive plug 16 suppresses the abrasion at the interface. This indicates that the adhesion does not rely on the size of the contact area, allowing further reduction in the size of element.

Note that, as the materials comprising the interlayer insulating film 14, the conductive plug 16, the lower electrode 7, the variable resistance layer 8, and the upper electrode 9, various materials illustrated in the manufacturing method according to the embodiment 1 may be used.

When a predetermined electrical pulse is applied on the variable resistance layer 8 included in the variable resistance element 10, the state of the variable resistance layer 8 changes between the predetermined low resistance state and high resistance state. Unless a new predetermined electrical pulse is applied, the variable resistance layer 8 maintains the state after the change. Accordingly, by associating “0” and “1” in the binary data to the low resistance state and the high resistance state of the variable resistance layer 8, respectively, the variable resistance element 10 can store binary data. Note that, the density of the current of the electrical pulse applied on the variable resistance layer 8, and the intensity of the electric field generated by the application of the electrical pulse may be sufficient to change the state in the variable resistance layer 8 and in a level that does not break the variable resistance layer 8. In addition, the electrical pulse may be applied on the variable resistance layer 8 more than once.

FIG. 5 illustrates operating characteristics of the variable resistance element 10 according to the embodiment 1, and is an operation example of current-voltage characteristics. The sample used for the measurement is a variable resistance element 10 formed by stacking the lower electrode 7, the variable resistance layer 8, and the upper electrode 9 deposited in order on the main surface of the substrate 1 by the sputtering method, and subsequently processed and formed using the regular lithography and dry etching. The variable resistance layer 8 in this sample comprises tantalum oxide (TaOₓ) having the thickness of 50 nm. The lower electrode 7 of this sample comprises tantalum nitride (TaN), and the upper electrode 9 of this sample is made of platinum (Pt), and the area of the electrode in the variable resistance element 10 is 0.5 μm².

In the measurement illustrated in FIG. 5, the voltage applied on the variable resistance element 10 changes from 0 V to −1.8 V (characteristics at this time is the curve along the arrow 1), from −1.8 V to 0 V (characteristics at this time is the curve along the arrow 2), from 0 V to +1.3 V (characteristics at this time is the curve along the arrow 3), and from +1.3 V to 0 V (characteristics at this time is the curve along the arrow 4) in order.

In FIG. 5, the change in the current value along the change in the resistance values of the variable resistance element 10 can be seen when the voltage applied on the variable resistance element 10 is approximately −0.8 V (illustrated as A in FIG. 5), and approximately +0.9 V (illustrated as B in FIG. 5). Accordingly, the maximum current flowing in the variable resistance element 10 at the time of the resistance change is approximately 80 μA. Therefore, it is assumed that current having high density greater than or equal to 10000 A/cm² is necessary for writing data on the variable resistance element 10.

The following shall describe results of the planarization by polishing the upper surface of the interlayer insulating film 14 with reference to FIGS. 6(a) and (b) to FIGS. 9(a) and (b). More specifically, the result of the observation on the state of the surface of the interlayer insulating film 14 and the conductive plug 16 before and after the process for planarizing by polishing the upper surface of the interlayer insulating film 14 (process 1005) shall be described.

The samples used for the observation were manufactured through the process 1000 to the process 1004 in FIG. 1. The interlayer insulating films 14 in the samples comprises P-TEOS, and the conductive plugs 16 comprise tungsten (W). Note that, the diameter of the contact hole 15 is approximately 0.3 μm on the upper surface of the interlayer insulating film 14.

(a) in FIG. 6 and (a) in FIG. 7 are AFM images captured by observing the unevenness on the surface near the conductive plugs 16 before the process 1005 is performed through an atomic force microscope (AFM). (a) in FIG. 6 shows an AFM image captured by observing the unevenness on the surface near densely formed conductive plugs 16. (a) in FIG. 7 shows an AFM image captured by observing the unevenness near an isolated conductive plug 16. Note that, the shortest distance between centers of adjacent conductive plugs 16 in the sample illustrated in (a) in FIG. 6 is approximately 1.5 μm.

In (a) in FIG. 6 and (a) in FIG. 7, the size of the area observed by the AFM (the area surrounded by a black edge) is a square of 20 μm. In the AFM images illustrated in (a) in FIG. 6 and (a) in FIG. 7, the conductive plugs were observed as images of black dots. This shows that the conductive plugs 16 are recessed from the upper surface of the interlayer insulating film 14.

(b) in FIG. 6 is a chart illustrating unevenness on the surface of the sample across the line VI-VI in (a) in FIG. 6. (b) in FIG. 7 is a chart illustrating unevenness on the surface of the sample across the line VII-VII in (a) in FIG. 7. In (b) in FIG. 6 and (b) in FIG. 7, the vertical axes represent a relative height (nm) and the horizontal axes represent a relative distance (μm). A1 to A5 in (b) in FIG. 6 correspond to depressions A1 to A5 in (a) in FIG. 6 caused by the conductive plugs 16 on the line VI-VI in (a) in FIG. 6. B1 in (b) in FIG. 7 corresponds to a depression B1 in (a) in FIG. 7 caused by the conductive plug 16 on the line VII-VII in (a) in FIG. 7.

When comparing (b) in FIG. 6 and (b) in FIG. 7, the amounts of depression on the conductive plugs 16 (the height from the top of the conductive plug 16 to the uppermost surface of the interlayer insulating film 14) are different. While the maximum unevenness in (b) in FIG. 6 is approximately 20 nm, the maximum unevenness in (b) in FIG. 7 is approximately 40 nm. The results overall reflect the depressions on the upper surface of the conductive plugs 16 due to the over-polishing and the depressions on the upper surface of the interlayer insulating film 14 by the recesses and erosion depending on the polishing conditions and the density of the conductive plugs 16.

When the amounts of depressions in A1 to A5 in (b) in FIG. 6 are compared, the variation in the amounts of the depressions in the conductive plugs 16 and the interlayer insulating film 14 is observed. The variation indicates the variation in the thickness of the interlayer insulating films 14 and the variation in the thickness of the conductive plugs 16.

(a) in FIG. 8 and (a) in FIG. 9 are AFM images after the process 1005 for planarizing by polishing the upper surface of the interlayer insulating film 14 is performed on the sample in (a) in FIG. 6 and (a) in FIG. 7, respectively. In the process 1005, the interlayer insulating film 14 is polished for an approximately 50 nm using a slurry including silica as an abrasive. Note that, the polishing time is determined by measuring an actual polishing speed for P-TEOS used for the interlayer insulating film 14, and calculating a time necessary for polishing in order to remove P-TEOS for 50 nm.

The left half of (a) in FIG. 8 is an AFM image captured by observing the unevenness on the surface of an area in which no conductive plug 16 is formed, and the right half of (a) in FIG. 8 is an AFM image captured by observing the unevenness on the surface of the region in which the conductive plugs 16 are densely formed. (a) in FIG. 9 is an AFM image captured by observing the unevenness near the conductive plug isolated in the same manner as in (a) in FIG. 7. Note that, the sample illustrated in (a) in FIG. 8 is obtained by performing the process 1005 on the sample in (a) in FIG. 6, and the shortest distance between the centers of the conductive plugs 16 is approximately 1.5 μm.

In (a) in FIG. 8 and (a) in FIG. 9, the size of the area observed by the AFM (the area surrounded by a black edge) is a square of 20 μm, in the same manner as (a) in FIG. 6 and (a) in FIG. 7. In the AFM images illustrated in (a) in FIG. 8 and (a) in FIG. 9, the conductive plugs 16 were observed as images of white dots. This shows that the conductive plugs 16 protrude from the upper surface of the interlayer insulating film 14.

(b) in FIG. 8 is a chart illustrating unevenness on the surface of the sample across the line VIII-VIII in (a) in FIG. 8. (b) in FIG. 9 is a chart illustrating unevenness on the surface of the sample across the line IX-IX in (a) in FIG. 9. In (b) in FIG. 8 and (b) in FIG. 9, the vertical axes represent a relative height (nm) and the horizontal axes represent a relative distance (μm). C1 to C3 in (b) in FIG. 8 correspond to protrusions C1 to C3 in the conductive plugs 16 on the line VIII-VIII in (a) in FIG. 8. D1 in (b) in FIG. 9 corresponds to a protrusion D1 in the conductive plug 16 on the line IX-IX in (a) in FIG. 9.

The comparison between (b) in FIG. 8 and (b) in FIG. 6 shows that the interlayer insulating film 14 in the proximity of the conductive plugs 16 is planarized in the process 1005. The comparison between (b) in FIG. 9 and (b) in FIG. 7 show the similar results. For example, the projection in D1 in (b) in FIG. 9 is sharp in the rising edge and narrow in width, compared to the depressed shape in B1 of (b) in FIG. 7. This is because the recess in the interlayer insulating film 14 formed in tapered shape in the upper part of the contact hole 15 is planarized by the process 1005.

The comparison between the left side region (an area where no conductive plug 16 is present) and the right side region (an area where the conductive plugs 16 are densely formed) in (b) in FIG. 8 shows that the upper surface of the interlayer insulating film 14 is flat. It illustrates that the erosion which occurs depending on the density of the conductive plugs 16 is solved by the process 1005.

The results of the experiment show that the upper surface of the interlayer insulating film 14 is planarized by the process 1005.

The following is the description of the protruding part of the conductive plugs 16. In (b) in FIG. 8 and (b) in FIG. 9, the protruding parts of the conductive plugs 16 stand substantially vertical to the main surface of the substrate. This indicates that the conductive plugs 16 are not deformed even if mechanical shock is exerted on the protruding parts of the conductive plugs 16 at the time of polishing in the process 1005. In (b) in FIG. 8 and (b) in FIG. 9, the maximum amount of protrusion of the conductive plugs 16 (the height from the upper surface of the interlayer insulating film 14 to the top of the conductive plug 16) is approximately 30 nm. The conductive plug 16 comprising tungsten (W) preferably has the amount of protrusion smaller than or equal to 30 nm in order to avoid mechanical deformation.

Furthermore, as illustrated in (b) in FIG. 8 and (b) in FIG. 9, the amount of protrusion of the conductive plugs 16 is different depending on the density of the conductive plugs 16. While the maximum protrusion amount in (b) in FIG. 8 is approximately 30 nm, the maximum unevenness in (b) in FIG. 9 is approximately 20 nm. This is because the amount of depression in the conductive plugs 16 by the over-polishing in the preceding process 1004 is reflected as the height of the conductive plugs 16 in the process 1005 substantially without any change. More specifically, the maximum unevenness in (b) in FIG. 6 is approximately 20 nm before the process 1005 is performed (corresponding to (e) in FIG. 2), while the maximum unevenness in (b) in FIG. 7 is approximately 40 nm. More specifically, in comparison with (b) in FIG. 6, a deeper depression from the upper surface of the conductive plug is formed in (b) in FIG. 7. Subsequently, the process 1005 for polishing the upper surface of the interlayer insulating film 14 is performed. After the process 1005 (corresponding to (a) in FIG. 3), the amount of protrusion of the conductive plugs 16 illustrated in (b) in FIG. 8 is greater than the amount of protrusion of the conductive plug 16 illustrated in (b) in FIG. 9.

Note that, the variation in the height of the conductive plugs 16 is solved by the upper surface of the lower electrode 7 by planarizing the surface through polishing the lower electrode 7 in the subsequent process 1007. More specifically, even if there is a variation in the height of the conductive plug 16, it is possible to secure the flatness of the upper surface of the lower electrode 7.

If the variable resistance element is manufactured by the manufacturing method according to the embodiment 1, the variation in the height of the conductive plugs caused by the depressions and erosion in the interlayer insulating film is solved by the upper surface of the lower electrode 7. With this, it is possible to reduce the variation in the characteristics of the variable resistance elements.

### Embodiment 2

FIG. 10 is a cross-sectional view schematically illustrating the configuration of a 1T1R memory cell 200 according to the embodiment 2. In FIG. 10, the same reference numerals are assigned to the components identical to the components in FIG. 4, and the description of the components is omitted. The variable resistance element 20 according to the embodiment 2 includes the variable resistance layer 8 having a variable resistance value reversibly changes based on the application of an electrical pulse disposed between the lower electrode 70 and the upper electrode 9. However, unlike the embodiment 1, a lower electrode 70 in the embodiment 2 has a stacked structure including a first lower electrode 70a and a second lower electrode 70b. With this configuration, a material difficult to be planarized by polishing may be used for the lower electrode 70 in the variable resistance element 20.

A flow of the processes in a method for manufacturing the variable resistance element 20 according to the embodiment 2 shall be described in order with reference to FIG. 11. FIG. 11 is a flowchart illustrating an example of the method for manufacturing the variable resistance element according to the embodiment 2.

Note that, in the embodiment 2, the process flow until the process 1005 (planarize the interlayer insulating film 14 exposed to the main surface of the substrate 1 by polishing according to the CMP method) is identical to the embodiment 1. Accordingly, the process flow after the process 1005 shall be described.

Next, the film for the first lower electrode 70a is formed on the interlayer insulating film 14 and the conductive plug 16 in the process 2001 using the CVD method, the sputtering method, or others. Since the upper part of the conductive plug 16 protrudes from the upper surface of the interlayer insulating film 14 ((a) in FIG. 3) due to the preceding process 1005, a film for forming the first lower electrode 70a is formed along the protruding shape. Consequently, the first lower electrode 70a has a protruding shape on the conductive plug 16.

In the process 2002, the protruding shape on the upper surface of the first lower electrode 70a formed in the preceding process 2001 is polished using the CMP method, and the first lower electrode 70a having a flat surface is obtained.

The first lower electrode 70a comprises various metal materials or conductive compounds. It is preferable that the first lower electrode 70a comprises tungsten (W), titanium (Ti), a compound of tungsten or titanium (tungsten nitride (WN), titanium nitride (TiN) or others), tantalum (Ta) or a compound of tantalum (tantalum nitride (TaN) or others). There is an advantage in terms of processing (such as sharing the polishing conditions) by using the materials for the first lower electrode 70a. Furthermore, these materials are known as refractory metals, and highly resistant to electromigration, and thus preferable for the variable resistance element 20 in terms of characteristics and stability of the element.

In the same manner as the process 1007 in the embodiment 1, it is necessary to control the thickness when performing polishing in the CMP process in the process 2002. Alternatively, in the process 2002, after a coated layer such as a resist is formed on the entire main surface of the substrate, the entire surface may be etched back, for example. Here, it is necessary to smooth the upper surface of the material for the first lower electrode 70a over the entire main surface of the substrate.

Next, in the process 2003, a film for forming the second lower electrode 70b is formed on the first lower electrode 70a planarized by polishing in the preceding process 2002. The second lower electrode 70b is made of various metal materials or conductive compounds. Since the surface of the first lower electrode 70a is planarized by polishing in the preceding process 2002, the surface of the second lower electrode 70b is flat as well. Accordingly, a material difficult to be planarized by polishing may be used for the second lower electrode 70b. With this, it is possible to configure the variable resistance element 20 having high flexibility in design. For example, precious metals such as platinum (Pt), iridium (Ir), palladium (Pd) and others in which the resistance change is likely to occur as described in the embodiment 1 may be selected as the second lower electrode 70b regardless of the limitation in processing.

Note that, in the embodiment 2, the lower electrode 70 is a stacked structure including the first lower electrode 70a and the second lower electrode 70b. However, it is not limited to this example. For example, the second lower electrode 70b may be a stacked structure including two or more layers, and the lower electrode 70 as a whole may be a stacked structure including three or more layers.

The lower electrode 70 is formed by the process 2001 to the process 2003 described above. Since the subsequent processes are identical to the processes 1008 and 1009 in the embodiment 1, the description for the processes is omitted.

According to the manufacturing method according to the embodiment 2, it is possible to loosen the limitation on processing the electrodes by increasing the options for the materials used for the lower electrode, in addition to the actions and effects described in the embodiment 1. This leads to an increased flexibility in designing the variable resistance element.

### Embodiment 3

(a) and (b) in FIG. 12 are cross-sectional views schematically illustrating configurations of 1D1R (one diode and one resistor) memory cells 300 and 301 according to the embodiment 3. In (a) and (b) in FIG. 12, the same reference numerals are assigned to the components identical to the components in FIG. 4, and the description of the components is omitted. The 1D1R memory cell 300 according to the embodiment 3 includes a current steering element 30 provided on the variable resistance element 10 having the same configuration as in the embodiment 1, as illustrated in (a) in FIG. 12. As illustrated in (b) in FIG. 12, the 1D1R memory cell 301 according to the embodiment 3 includes the variable resistance element 10 including the components stacked on a reverse order, disposed on the current steering element 30 including the components stacked in a reverse order, compared to (a) in FIG. 12.

In a storage device known as a cross-point storage device in which the 1D1R memory cells including the variable resistance element 10 and the current steering element 30 according to the embodiment 3, bypass current flowing in memory cells (non-selected memory cell) other than a selected memory cell are generated when writing information on a predetermined memory cell (selected memory cell) and when reading the information from the predetermined memory cell. When writing the information on the selected memory cell or when reading the information out of the selected memory cell, if the value of the bypass current in the non-selected memory cells reaches a non-negligible value and exceeds a predetermined threshold, incorrect information may be written on the non-selected memory cells or incorrect information may be read out of the selected memory cell. Accordingly, it is crucial to prevent the bypass current from flowing in the non-selected memory cells.

In the embodiment 3, as illustrated in (a) and (b) in FIG. 12, the current steering element 30 is connected to the variable resistance element 10 in series, and prevents the bypass current from flowing in the non-selected memory cells which are memory cells other than the predetermined selected memory cell. With this, it is possible to prevent a write disturb (a failure including change in the resistance value of the variable resistance element 10 in the non-selected memory cell) when writing data on the variable resistance element 10 and a reading error in the selected memory cell.

When the variable resistance element 10 is a unipolar variable resistance element, the resistance value of the variable resistance layer 8 changes by an electrical pulse having the same polarity (for example, a voltage pulse). Accordingly, a unipolar current steering element (having non-linear voltage-current characteristics having a high resistance state and a low resistance state in a voltage range of the same polarity) can be used as the current steering element 30. As the current steering element, a p-n junction diode, a Schottky diode, or others can be used.

When the variable resistance element 10 is a bipolar variable resistance element, the resistance value of the variable resistance layer 8 changes based on bipolar electrical pulses (for example, positive and negative electrical pulses). Accordingly, a bipolar current steering element (having non-linear voltage-current characteristics having a high resistance state and a low resistance state in a voltage range of the positive/negative polarity) can be used as the current steering element 30. As the current steering element 30, two-terminal devices such as a metal-insulator-metal (MIM) diode, a metal-semiconductor-metal (MSM) diode, a varistor, or others is used.

In the 1D1R memory cell 300 illustrated in (a) in FIG. 12, the current steering element 30 shares the upper electrode 9 with the variable resistance element 10 as one of the diode electrodes, and further includes a current steering layer 31 and the other diode electrode 32 above the diode electrode 9. The upper electrode 9 functions as an electrode in the variable resistance element 10 and also as an electrode in the current steering element 30.

The 1D1R memory cell 301 illustrated in (b) in FIG. 12 includes components included in the memory cell 300 in (a) in FIG. 12 stacked in a reverse order. Accordingly, the lower electrode 19 and the upper electrode 17 in the memory cell 301 are composed of the same materials as the upper electrode 9 and the lower electrode 7 of the memory cell 300, and the current steering element 50 and the variable resistance element 40 in the memory cell 301 serve the same functions as the current steering element 30 and the variable resistance element 10 in the memory cell 300, respectively.

Note that, in (a) in FIG. 12, it is not necessary for the upper electrode 9 in the variable resistance element 10 to be shared with the current steering element 30 as a diode electrode. For example, the variable resistance element 10 and the current steering element 30 spatially apart from each other may be electrically connected. The same configuration is applicable to (b) in FIG. 12.

Furthermore, for simplification purpose, (a) and (b) in FIG. 12 and the following description illustrate the current steering elements 30 and 50 are MSM diodes. However, the embodiment 3 is not limited to this example. The 1D1R memory cells 300 and 301 may include the current steering elements 30 and 50 in addition to the variable resistance elements 10 and 40. For example, the current steering elements 30 and 50 may be current steering elements having other structure such as MIM diodes.

The method for manufacturing the variable resistance element to which the current steering element is connected in series according to the embodiment 3 shall be described with reference to FIG. 13. FIG. 13 is a flowchart illustrating an example of the method for manufacturing the variable resistance element, and more specifically, the memory cell 300 in (a) in FIG. 12.

First, the substrate 1 is prepared in the process 3000. It is not necessary for the 1D1R memory cells 300 and 301 according to the embodiment 3 to include the selection transistor 6 inside the memory array as illustrated in the embodiment 1. For example, in (a) and (b) in FIG. 12, the metal line 33 which serves as the word line is included in the substrate 1.

In the following description, the description for the process 1001 to the process 1008 is omitted, since the process flow is identical to the embodiment 1. Note that, as in the embodiment 2, the lower electrode 70 may have a two-layered structure.

After the variable resistance layer and the upper electrode layer are formed in the process 1008, the current steering layer 31 and the diode electrode 32 are deposited above the upper electrode 9, using the CVD method, the sputtering method, or others in the process 3001.

The current steering layer 31 comprises various semiconductors or insulators having rectifying property by potential barrier at the surface of the junction with the electrode material. For example, when the current steering element 30 is an MSM diode, the current steering layer 31 comprises amorphous silicon, polysilicon, silicon nitride (SiNₓ (0<x≦0.85)), or others. More specifically, the MSM diode using silicon nitride (SiNₓ) is a desirable material since SiNₓ is suitable for flowing current having high current density. The detailed description of the results of the experiment is disclosed in the patent literature 8: WO2008/117494. Accordingly, the detailed description for the experiment results is omitted here.

The upper electrode 9 and the diode electrode 32 comprise various metal materials having rectifying property at a surface of a junction with the current steering layer 31, or a compound having conductive property. Examples of the metal materials include metals such as Al, Cu, Ti, W, Pt, Ir, Cr, Ni, Nb, or others, or mixture (alloy) or stacked structures of the metals. Examples of the conductive compounds include TiN, TiW, TaN, TaSi₂, TaSiN, TaAlN, NbN, WN, WSi₂, WSiN, RuO₂, In₂O₃, SnO₂, IrO₂, or others, or mixture or stacked structure of the conductive compounds.

In the process 3002, the stacked structure including the lower electrode 7, the variable resistance layer 8, the upper electrode 9, the current steering layer 31, and the diode electrode 32 are processed and formed by the dry etching or others. With this process, the variable resistance element 10 and the current steering element 30 are formed as illustrated in FIG. 12. Here, it is assumed that the stacked structure is collectively formed by dry etching. However, it is not limited to this example, and each layer may be individually processed using multiple photo masks, for example.

As described above, according to the manufacturing method according to the embodiment 3, forming the current steering element on the variable resistance element allows forming the variable resistance element and the current steering element by etching at once, in addition to the actions and effects described in the embodiment 1.

The memory cell 301 in (b) in FIG. 12 can be manufactured according to a process flow in which the processes included in the flowchart in FIG. 13 are switched where appropriate.

Although only some exemplary embodiments have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

For example, in (a) to (e) in FIG. 2 and (a) to (e) in FIG. 3, the process for manufacturing the variable resistance element is described using an example in which one conductive plug 16 is formed inside one contact hole 15. In contrast, (a) and (b) in FIG. 6 and (a) and (b) in FIG. 8 illustrate examples of samples having multiple conductive plugs manufactured based on the manufacturing method. More specifically, it is clear that the manufacturing method according to the present invention is not limited to the method for manufacturing one variable resistance element connected to one conductive plug but is also applicable to the manufacturing of multiple variable resistance elements formed on multiple conductive plugs.

Accordingly, the method for manufacturing multiple variable resistance elements including forming an interlayer insulating film on a substrate; forming contact holes in the interlayer insulating film; depositing a conductive material in the contact holes and on the interlayer insulating film; forming conductive plugs in the contact holes by removing the conductive material deposited on the interlayer insulating film; planarizing an upper surface of the interlayer insulating film such that an upper part of the conductive plugs protrudes from an upper surface of the interlayer insulating film by removing (i) a depression (recess) in the interlayer insulating film formed around the conductive plug and (ii) a depression (erosion) in the interlayer insulating film formed across a plurality of the conductive plugs; forming, on the interlayer insulating film and the conductive plugs, a lower electrode layer electrically connected to the conductive plugs; planarizing an upper surface of the lower electrode layer so as to remove a protruding part on the upper surface of the lower electrode layer; forming, on the lower electrode layer, a variable resistance layer having a resistance value reversibly changes based on an application of an electric pulse; forming an upper electrode layer on the variable resistance layer; and removing a stacked structure including the lower electrode layer, the variable resistance layer, and the upper electrode layer, leaving a part of the stacked structure in the proximity of the conductive plug is included in the present invention.

### INDUSTRIAL APPLICABILITY

The present invention is applicable to a method for manufacturing a variable resistance element in which a resistance value reversibly changes based on an electrical signal, and a method for manufacturing a storage device using the variable resistance element.

### REFERENCE SIGNS LIST

1, 901 Substrate
2, 902 Source region
3, 903 Drain region
4, 904 Gate oxide film
5, 905 Gate electrode
6, 906 Selection transistor
7, 70, 907 Lower electrode
8, 908 Variable resistance layer
9 Upper electrode (diode electrode)
10, 20, 40, 910 Variable resistance element
14, 914 Interlayer insulating film
15, 915 Contact hole
16, 916 Conductive plug (conductive material)
17 Upper electrode
19 Lower electrode (diode electrode)
30, 50 Current steering element
31 Current steering layer
32 Diode electrode
33, 912, 913 Metal line
70a First lower electrode
70b Second lower electrode
100, 200, 300, 301, 900 Memory cell
909 Upper electrode
917, 918 Conductive plug

1. A method for manufacturing a variable resistance element comprising:
forming an interlayer insulating film on a substrate;
forming a contact hole in the interlayer insulating film;
depositing a conductive material in the contact hole and on the interlayer insulating film;
forming a conductive plug in the contact hole by removing the conductive material deposited on the interlayer insulating film;
planarizing an upper surface of the interlayer insulating film such that an upper part of the conductive plug protrudes from an upper surface of the interlayer insulating film by removing (i) a depression in the interlayer insulating film formed around the conductive plug and (ii) a depression in the interlayer insulating film formed across a plurality of the conductive plugs;
forming, on the interlayer insulating film and the conductive plug, a lower electrode layer electrically connected to the conductive plug;
planarizing an upper surface of the lower electrode layer so as to remove a protruding part on the upper surface of the lower electrode layer;
forming, on the lower electrode layer, a variable resistance layer having a resistance value reversibly changing based on an application of an electric pulse;
forming an upper electrode layer on the variable resistance layer;
forming, on the upper electrode layer, a semiconductor layer or an insulator layer;
forming a diode electrode layer on the semiconductor layer or the insulator layer; and
removing a stacked structure including the lower electrode layer, the variable resistance layer, the upper electrode layer, the semiconductor layer or insulator layer, and the diode electrode layer, leaving a part of the stacked structure in the proximity of the conductive plug.

2. The method for manufacturing the variable resistance element according to claim 1,
wherein a chemical mechanical polishing (CMP) method is used for planarizing the upper surface of the interlayer insulating film.

3. The method for manufacturing the variable resistance element according to claim 1,
wherein the chemical mechanical polishing (CMP) method is used for planarizing the upper surface of the lower electrode layer.

4. The method for manufacturing the variable resistance element according to claim 1,
wherein a dry etching method is used for removing the stacked structure, leaving the part of the stacked structure in the proximity of the conductive plug.

5. (canceled)

6. The method for manufacturing the variable resistance element according to claim 1,
wherein the forming the lower electrode layer further includes:
forming, on the interlayer insulating film and the conductive plug, a first lower electrode layer electrically connected to the conductive plug; and
forming, on the first lower electrode layer, a second lower electrode layer comprising a material different from the first lower electrode layer.

7. (canceled)

8. A method for manufacturing a variable resistance element, comprising:
forming an interlayer insulating film on a substrate;
forming a contact hole in the interlayer insulating film;
depositing a conductive material in the contact hole and on the interlayer insulating film;
forming a conductive plug in the contact hole by removing the conductive material deposited on the interlayer insulating film;
planarizing an upper surface of the interlayer insulating film such that an upper part of the conductive plug protrudes from an upper surface of the interlayer insulating film by removing (i) a depression in the interlayer insulating film formed around the conductive plug and (ii) a depression in the interlayer insulating film formed across a plurality of the conductive plugs;
forming, on the interlayer insulating film and the conductive plug, a diode electrode layer electrically connected to the conductive plug;
planarizing an upper surface of the diode electrode layer so as to remove a protruding part on the upper surface of the diode electrode layer;
forming, on the diode electrode layer, a semiconductor layer or an insulator layer;
forming, on the semiconductor layer or the insulator layer, a lower electrode layer;
forming, on the lower electrode layer, a variable resistance layer having a resistance value reversibly changing based on an application of an electric pulse;
forming an upper electrode layer on the variable resistance layer; and
removing a stacked structure including the diode electrode layer, the semiconductor layer or insulator layer, the lower electrode layer, the variable resistance layer, and the upper electrode layer, leaving a part of the stacked structure in the proximity of the conductive plug.

9. The method for manufacturing the variable resistance element according to claim 1,
wherein the lower electrode layer is formed on the interlayer insulating film and the conductive plug, the lower electrode layer having a thickness greater than or equal to an amount of protrusion of the conductive plug.

10. The method for manufacturing the variable resistance element according to claim 1,
wherein the conductive plug formed comprises tungsten (W), and
when forming the lower electrode, the lower electrode layer is formed to cover the protruding part of the conductive plug, the lower electrode layer comprising one of titanium (Ti), tantalum (Ta), tungsten (W), titanium nitride (TiN), tantalum nitride (TaN), and tungsten nitride (WN).
